(19) United States
(12) Patent Application Publication
(10) Pub. No.: US 2026/0362855 A1
(43) Pub. Date: Nov. 12, 2026

(54) NITRIDE SEMICONDUCTOR LIGHT-EMITTING ELEMENT

(71) Applicant: NIKKISO CO., LTD., Tokyo (JP)

(72) Inventors: Yusuke MATSUKURA, Ishikawa (JP); Cyril PERNOT, Ishikawa (JP); Kazufumi TAKAO, Ishikawa (JP)

(73) Assignee: NIKKISO CO., LTD., Tokyo (JP)

(21) Appl. No.: 18/588,668

(22) Filed: Feb. 27, 2024

(30) Foreign Application Priority Data
Feb. 28, 2023 (JP) 2023-029186

(51) Int. Cl. H10H 20/825; H10H 20/812

(52) U.S. Cl. CPC H10H 20/825; H10H 20/812

(57) ABSTRACT

A nitride semiconductor light-emitting element includes an n-type semiconductor layer including Al, Ga and N, an active layer that is formed on one side of the n-type semiconductor layer and has a multiple quantum well structure with a plurality of well layers comprising Al, Ga and N, and a p-type semiconductor layer formed on a side of the active layer opposite to the n-type semiconductor layer. Silicon is included in the active layer. A full width at half maximum of an X-ray rocking curve for a (10-12) plane of the n-type semiconductor layer is not more than 812 arcsec.

### CROSS-REFERENCE TO RELATED APPLICATIONS

The present application is based on Japanese patent application No. 2023-029186 filed on Feb. 28, 2023, the entire contents of which are incorporated herein by reference.

### TECHNICAL FIELD

The present invention relates to a nitride semiconductor light-emitting element.

### BACKGROUND OF THE INVENTION

Patent Literature 1 discloses a nitride semiconductor element that has an n-type cladding layer made of n-type AlGaN and an active layer made of AlGaN. Patent Literature 1 discloses that light output of the nitride semiconductor element is improved by setting an n-AlGaN mix value, which is a full width at half maximum of an X-ray rocking curve for a (10-12) plane of the n-type cladding layer, to not more than 500 arcsec.
Citation List Patent Literature 1: JP 2019-121655A

### SUMMARY OF THE INVENTION

It was newly found that when having a precondition configuration in which silicon is included in the active layer, the relationship between the n-AlGaN mix value and the light output is different as compared to when silicon is not included in the active layer.

The invention was made in view of such circumstances and it is an object of the invention to provide a nitride semiconductor light-emitting element that can achieve improved light output in case that silicon is included in the active layer.

To achieve the object described above, the invention provides a nitride semiconductor light-emitting element, comprising:
an n-type semiconductor layer comprising Al, Ga and N;
an active layer that is formed on one side of the n-type semiconductor layer and has a multiple quantum well structure with a plurality of well layers comprising Al, Ga and N; and
a p-type semiconductor layer formed on a side of the active layer opposite to the n-type semiconductor layer,
wherein a full width at half maximum of an X-ray rocking curve for a (10-12) plane of the n-type semiconductor layer is not more than 812 arcsec, and wherein silicon is included in the active layer.

### Advantageous Effects of the Invention

According to the invention, it is possible to provide a nitride semiconductor light-emitting element that can achieve improved light output in case that silicon is included in the active layer.

### BRIEF DESCRIPTION OF DRAWINGS

FIG. 1 is a schematic diagram illustrating a configuration of a nitride semiconductor light-emitting element in an embodiment.

FIG. 2 is a graph showing a relationship between n-AlGaN mix value and light output in Experimental Example.

### DETAILED DESCRIPTION OF THE INVENTION

### Embodiment

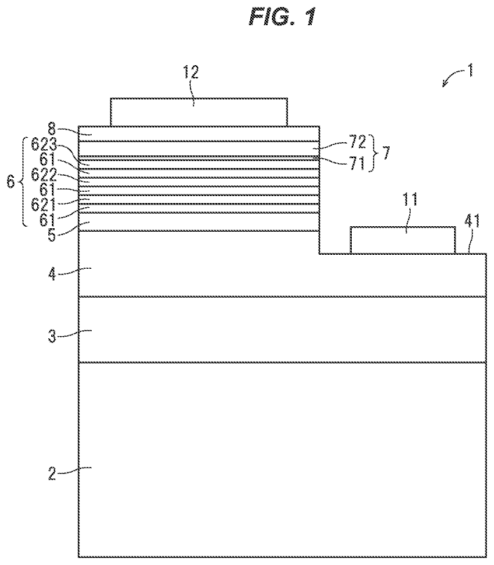

An embodiment of the invention will be described in reference to FIG. 1. The embodiment below is described as a preferred illustrative example for implementing the invention. Although some part of the embodiment specifically illustrates various technically preferable matters, the technical scope of the invention is not limited to such specific aspects.

### Nitride Semiconductor Light-Emitting Element 1

FIG. 1 is a schematic diagram illustrating a configuration of a nitride semiconductor light-emitting element 1. In FIG. 1, the scale ratio in a direction of stacking each layer of the nitride semiconductor light-emitting element 1 (hereinafter, also simply referred to as “the light-emitting element 1”) is not necessarily the same as the actual scale ratio. Hereinafter, the direction of stacking each layer of the light-emitting element 1 is referred to as the up-and-down direction. In addition, one side in the up-and-down direction, which is a side of a substrate 2 where each semiconductor layer is grown, (e.g., an upper side in FIG. 1) will be referred to as the upper side, and the opposite side (e.g., a lower side in FIG. 1) will be referred to as the lower side. In this regard, the terms “upper” and “lower” are used for descriptive purposes and do not limit the posture of the light-emitting element 1 with respect to the vertical direction when, e.g., the light-emitting element 1 is used.

The light-emitting element 1 is, e.g., a light-emitting diode (LED) or a semiconductor laser (LD: laser diode). In the present embodiment, the light-emitting element 1 is a light-emitting diode that emits light with a wavelength in an ultraviolet region. Particularly, the light-emitting element 1 in the present embodiment emits ultraviolet light at a central wavelength of not less than 250 nm and not more than 365 nm. The light-emitting element 1 can be used in fields such as, e.g., sterilization (e.g., air purification, water purification, etc.), medical treatment (e.g., light therapy, measurement/analysis, etc.), UV curing, etc.

The light-emitting element 1 includes a buffer layer 3, an n-type cladding layer 4, a composition gradient layer 5, an active layer 6, an electron blocking layer 7 and a p-type semiconductor layer 8 in this order on the substrate 2. The light-emitting element 1 also includes an n-side electrode 11 provided on the n-type cladding layer 4, and a p-side electrode 12 provided on the p-type semiconductor layer 8.

As semiconductors constituting the light-emitting element 1, it is possible to use, e.g., binary to quaternary group III nitride semiconductors expressed by AlₐGa_{b}In_{1-a-b}N (0≤a≤1, 0≤b≤1, 0≤a+b≤1). In the present embodiment, binary or ternary group III nitride semiconductors expressed by Al_{c}Ga_{1-c}N (0≤c≤1) are used as the semiconductors constituting the light-emitting element 1. These group III elements may be partially substituted with boron (B) or thallium (Tl), etc. In addition, nitrogen (N) may be partially substituted with phosphorus (P), arsenic (As), antimony (Sb) or bismuth (Bi), etc.

The substrate 2 is made of a material transparent to light emitted by the active layer 6. The substrate 2 is, e.g., a sapphire (Al₂O₃) substrate. An upper surface of the substrate 2 (i.e., a surface on which each semiconductor layer of the light-emitting element 1 is stacked) is a c-plane. This c-plane may have an off-angle. Alternatively, e.g., an aluminum nitride (AlN) substrate or an aluminum gallium nitride (AlGaN) substrate, etc., may be used as the substrate 2.

The buffer layer 3 is formed on the substrate 2. In the present embodiment, the buffer layer 3 is made of aluminum nitride. When the substrate 2 is an aluminum nitride substrate or an aluminum gallium nitride substrate, the buffer layer 3 may not be necessarily included. The buffer layer 3 may also include a semiconductor layer made of undoped AlₚGa₁₋ₚN (0≤p≤1) that is formed on the semiconductor layer made of aluminum nitride.

The n-type cladding layer 4 is an n-type semiconductor layer formed on the buffer layer 3. The n-type cladding layer 4 is made of, e.g., Al_{q}Ga_{1-q}N (0≤q≤1) doped with an n-type impurity. In the present embodiment, silicon (Si) is used as the n-type impurity. Alternatively, germanium (Ge), selenium (Se) or tellurium (Te), etc., may be used as the n-type impurity. An Al composition ratio q of the n-type cladding layer 4 is, e.g., preferably not less than 20%, and is more preferably not less than 25% and not more than 70%. In this regard, the Al composition ratio is also called AlN mole fraction. A film thickness of the n-type cladding layer 4 can be, e.g., not less than 1 m and not more than 4 μm.

A full width at half maximum of an X-ray rocking curve obtained by X-ray diffraction ω-scan on a (10-12) plane of n-type AlGaN crystal constituting the n-type cladding layer 4 (hereinafter, also referred to as the “n-AlGaN mix value”) is not more than 812 arcsec. The n-AlGaN mix value is an indicator of crystal quality of the n-type cladding layer 4, where the lower the value, the better the crystal quality of the n-type cladding layer 4. In case of the light-emitting device 1 in which silicon is included in the active layer 6, light output is improved by setting the n-AlGaN mix value to not more than 812 arcsec, as shown in Experimental Example described later. From the viewpoint of further improving the light output, the n-AlGaN mix value is preferably not more than 760 arcsec.

The n-type cladding layer 4 has a single layer structure in the present embodiment but may have a multilayer structure. When the n-type cladding layer 4 has a multilayer structure, the n-AlGaN mix value of the semiconductor layer closest to the active layer 6 among semiconductor layers constituting the n-type cladding layer 4 is not more than 812 arcsec (preferably not more than 760 arcsec). This is because it is considered that light emission intensity of the active layer 6 depends on crystallinity of the active layer 6, and the crystallinity of the active layer 6 depends on crystallinity of the semiconductor layer closest to the active layer 6 among the plural semiconductor layers of the n-type cladding layer 4.

The composition gradient layer 5 is formed on the n-type cladding layer 4. The composition gradient layer 5 is made of AlᵣGa₁₋ᵣN (0≤r≤1) doped with silicon. An Al composition ratio of the composition gradient layer 5 along the up-and-down direction is higher as closer the active layer 6. The composition gradient layer 5 may include, e.g., a very small region in the up-and-down direction (e.g., a region of not more than 5% of the entire composition gradient layer 5 in the up-and-down direction) in which the Al composition ratio does not increase toward the active layer 6.

The Al composition ratio of an end portion of the composition gradient layer 5 on the n-type cladding layer 4 side is preferably substantially the same (e.g., a difference within 5%) as the Al composition ratio of an end portion of the n-type cladding layer 4 on the composition gradient layer 5 side. In addition, the Al composition ratio of an end portion of the composition gradient layer 5 on the active layer 6 side is preferably substantially the same (e.g., a difference within 5%) as an Al composition ratio of an end portion of the active layer 6 on the composition gradient layer 5 side. A film thickness of the composition gradient layer 5 can be, e.g., not less than 5 nm and not more than 50 nm.

The active layer 6 is formed on the composition gradient layer 5. The active layer 6 has a multi quantum well structure which includes plural well layers 621 to 623. A band gap of the active layer 6 is adjusted so that ultraviolet light at a central wavelength of not less than 250 nm and not more than 365 nm can be emitted.

In the present embodiment, the active layer 6 has three barrier layers 61 and three well layers 621 to 623, and the barrier layers 61 and the well layers 621 to 623 are alternately stacked. In the active layer 6, the barrier layer 61 is located at an end on the composition gradient layer 5 side and the well layer 623 is located at an end on the electron blocking layer 7 side. In this regard, the number of barrier layers 61 and the number of well layers 621 to 623 in the active layer 6 are not particularly limited as long as there are not less than two well layers.

Each barrier layer 61 is made of AlₛGa₁₋ₛN (0<s<1). An Al composition ratio s of each barrier layer 61 is, e.g., not less than 75% and not more than 95%. Each barrier layer 61 has a film thickness of, e.g., not less than 2 nm and not more than 50 nm.

The well layers 621 to 623 are made of AlₜGa₁₋ₜN (0<t<1). An Al composition ratio t of each of the well layers 621 to 623 is smaller than the Al composition ratio s of the barrier layers 61 (i.e., t<s).

The three well layers 621 to 623 will be referred to as a first well layer 621, a second well layer 622, and a third well layer 623 in order from the composition gradient layer 5 side. A film thickness of the first well layer 621 is not less than 1 nm greater than a film thickness of each of the second well layer 622 and the third well layer 623. This results in that each layer of the active layer 6 becomes flat and monochromaticity of output light is improved. A difference between the film thickness of the first well layer 621 and the film thickness of each of the second well layer 622 and the third well layer 623 is preferably not less than 2 nm and not more than 4 nm. In the present embodiment, each of the second well layer 622 and the third well layer 623 has a film thickness of not less than 2 nm and not more than 4 nm and the first well layer 621 has a film thickness of not less than 4 nm and not more than 6 nm.

The Al composition ratio of the first well layer 621 is not less than 2% greater than the Al composition ratio of each of the second well layer 622 and the third well layer 623. By increasing the Al composition ratio of the first well layer 621 to higher than the Al composition ratio of each of the second well layer 622 and the third well layer 623, crystallinity of the first well layer 621 is improved. This is because the difference in the Al composition ratio between the first well layer 621 and the n-type cladding layer 4 is reduced. The improved crystallinity of the first well layer 621 improves crystallinity of each semiconductor layer formed on and above the first well layer 621 in the active layer 6. As a result, carrier mobility in the active layer 6 is improved and light output is improved. Such effects are more pronounced when the first well layer 621 has a larger film thickness, but the film thickness of the first well layer 621 is designed to be not more than a predetermined value from the viewpoint of suppressing an increase in the electrical resistance value of the entire light-emitting element 1.

In the present embodiment, each of the second well layer 622 and the third well layer 623 has an Al composition ratio of not less than 25% and not more than 45%, and the first well layer 621 has an Al composition ratio of not less than 35% and not more than 55%. The plural well layers 621 to 623 may be configured such that, e.g., the layer closer to the composition gradient layer 5 has a higher Al composition ratio.

Silicon is included in the active layer 6. In the present embodiment, a silicon source is not supplied during deposition of the active layer 6 as described later, and silicon present in each layer of the active layer 6 is diffused from the substrate 2 side of the active layer 6 in the light-emitting element 1. Silicon in the active layer 6 is likely to be incorporated particularly into positions with low Al composition ratio in the up-and-down direction of the active layer 6, and is also likely to be incorporated into a layer close to the composition gradient layer 5 among the layers of the active layer 6.

A silicon concentration in the barrier layers 61 is higher in the layer closer to the composition gradient layer 5, and similarly, a silicon concentration in the well layers 621 to 623 is higher in the layer closer to the composition gradient layer 5. In the present embodiment, the first well layer 621, which is the well layer closest to the n-type semiconductor layer among the plural well layers 621 to 623, has the highest silicon concentration among the layers of the active layer 6. The maximum value of the silicon concentration distribution in the active layer 6 in the up-and-down direction is preferably not less than 8.0×10¹⁸ atoms/cm³, and preferably not less than 1.0×10¹⁹ atoms/cm³ and not more than 6.0×10¹⁹ atoms/cm³. It has been confirmed that the light output of the light-emitting element 1 is likely to be improved when the maximum value of the silicon concentration distribution in the active layer 6 in the up-and-down direction is within the above numerical range.

Plurality pits (e.g., so-called V-pits; not shown) are formed in the active layer 6. As described later, during the production of the light-emitting element 1, the silicon source is supplied into the chamber before the deposition of the active layer 6 (in particular, after the deposition of the composition gradient layer 5 and before the deposition of the active layer 6), which changes the growth mode of the matrix phase of the semiconductor layer and forms pits in the active layer 6. It is considered that since pits are formed in the active layer 6, holes are easily supplied from the p-type semiconductor layer 8 to the active layer 6 through the pits, resulting in improvement in the light output of the light-emitting element 1. It is also considered that formation of pits in the active layer 6 is more likely to be induced by the presence of silicon in the active layer 6.

The electron blocking layer 7 is formed on the active layer 6. The electron blocking layer 7 serves to improve efficiency of electron injection into the active layer 6 by suppressing occurrence of the overflow phenomenon in which electrons leak from the active layer 6 to the p-type semiconductor layer 8 side (hereinafter, also referred to as the electron blocking effect). In the present embodiment, the electron blocking layer 7 is made of undoped AlᵤG₁₋ᵤN (0.7≤u≤1). In other words, the electron blocking layer 7 is configured as a semiconductor layer with an Al composition ratio u of not less than 70%. The electron blocking layer 7 has a stacked structure in which a first electron blocking layer 71 and a second electron blocking layer 72 are stacked in this order from the active layer 6 side. The electron blocking layer 7 may be formed of not less than three layers.

The first electron blocking layer 71 is provided so as to be in contact with the active layer 6. Among plural semiconductor layers (in the present embodiment, the first electron blocking layer 71 and the second electron blocking layer 72) constituting the electron blocking layer 7, the first electron blocking layer 71 has a higher Al composition ratio than that of the other semiconductor layers (i.e., the second electron blocking layer 72) constituting the electron blocking layer 7 and that of the barrier layers 61. The Al composition ratio of the first electron blocking layer 71 is, e.g., not less than 90% and may be 100% (i.e., the first electron blocking layer 71 may be made of AlN). A film thickness of the first electron blocking layer 71 is, e.g., not less than 0.5 nm and not more than 5.0 nm.

The Al composition ratio of the second electron blocking layer 72 is lower than the Al composition ratio of the first electron blocking layer 71 and is, e.g., not less than 70% and not more than 90%. A film thickness of the second electron blocking layer 72 is larger than the film thickness of the first electron blocking layer 71 and is, e.g., not less than 15 nm and not more than 100 nm.

When the first electron blocking layer 71 with a relatively high Al composition ratio has an excessively large film thickness, it causes an excessive increase in the electrical resistance value of the entire light-emitting element 1 since a semiconductor layer with a higher Al composition ratio has a higher electrical resistance value. For this reason, the film thickness of the first electron blocking layer 71 is preferably small to some extent. On the other hand, if the film thickness of the first electron blocking layer 71 is small, it increases the probability that electrons pass through the first electron blocking layer 71 from the active layer 6 side to the p-type semiconductor layer 8 side due to the tunnel effect. Therefore, in the light-emitting element 1 of the present embodiment, the second electron blocking layer 72 is formed on the first electron blocking layer 71 to suppress passage of electrons through the entire electron blocking layer 7.

Each of the first electron blocking layer 71 and the second electron blocking layer 72 can be an undoped layer, a layer containing an n-type impurity, a layer containing a p-type impurity, or a layer containing both an n-type impurity and a p-type impurity. Magnesium (Mg) can be used as the p-type impurity, but zinc (Zn), beryllium (Be), calcium (Ca), strontium (Sr), barium (Ba) or carbon (C), etc., may be used other than magnesium. The same applies to the other semiconductor layers containing the p-type impurity. When each electron blocking layer 7 contains an impurity, the impurity in each electron blocking layer 7 may be contained in the entire portion of each electron blocking layer 7 or may be contained in a part of each electron blocking layer 7. The electron blocking layer 7 may be composed of a single layer, or may be composed of not less than three layers, or may be omitted.

Silicon may be included between the electron blocking layer 7 and the p-type semiconductor layer 8. Magnesium is likely to be attracted to silicon and hydrogen is likely to bond to magnesium, hence, the presence of silicon between the electron blocking layer 7 and the p-type semiconductor layer 8 suppresses diffusion of magnesium and hydrogen from the p-type semiconductor layer 8 to the active layer 6 and the service life of the light-emitting element 1 is thereby extended. Furthermore, since silicon is included between the electron blocking layer 7 and the p-type semiconductor layer 8, a layer with pits may be formed between the electron blocking layer 7 and the p-type semiconductor layer 8. Pits are formed by the silicon source being supplied to locations where dislocations exist. Therefore, by formation of pits, propagation of dislocations above the pits is suppressed and the service life of the light-emitting element 1 is extended.

The p-type semiconductor layer 8 is formed on the electron blocking layer 7. The p-type semiconductor layer 8 is made of p-type AlᵥGa₁₋ᵥN (0≤v<0.7). That is, the p-type semiconductor layer 8 is configured as a semiconductor layer with an Al composition ratio of less than 70%.

The p-type semiconductor layer 8 has a p-type contact layer. The p-type contact layer is a layer connected to the p-side electrode 12 and is made of AlᵥGa₁₋ᵥN (0≤v<0.7) doped with a high concentration of a p-type impurity. The p-type contact layer is configured to have a low Al composition ratio to achieve an ohmic contact with the p-side electrode 12 and, from such a viewpoint, is preferably made of p-type gallium nitride. Semiconductor layers made of p-type gallium nitride are likely to absorb ultraviolet light. Therefore, from the viewpoint of preventing absorption of ultraviolet light and improving light output of the light-emitting device 1, a film thickness of the p-type contact layer is preferably not more than 30 nm. Further, from the viewpoint of suppressing occurrence of short circuits, the film thickness of the p-type contact layer is preferably not less than 5 nm.

The p-type semiconductor layer 8 may further include a p-type cladding layer on the electron blocking layer 7 side of the p-type contact layer. The p-type cladding layer is made of p-type AlGaN with an Al composition ratio of less than 70%. The p-type cladding layer may be composed of, e.g., a single layer or may be composed of plural layers. When the p-type cladding layer is composed of plural layers, the p-type cladding layer may have, e.g., a first p-type cladding layer formed on the second electron blocking layer 72 side and a second p-type cladding layer formed between the first p-type cladding layer and the p-type contact layer. An Al composition ratio of the second p-type cladding layer along the up-and-down direction may be such that the closer to the p-type contact layer, the lower the Al composition ratio. The second p-type cladding layer may include, e.g., a very small region in the up-and-down direction (e.g., a region of not more than 5% of the entire second p-type cladding layer in the up-and-down direction) in which the Al composition ratio does not decrease toward the p-type contact layer. The Al composition ratio of an end portion of the second p-type cladding layer on the first p-type cladding layer side is preferably substantially the same (e.g., a difference within 5%) as an Al composition ratio of an end portion of the first p-type cladding layer on the second p-type cladding layer side. In addition, the Al composition ratio of an end portion of the second p-type cladding layer on the p-type contact layer side is preferably substantially the same (e.g., a difference within 5%) as the Al composition ratio of an end portion of the p-type contact layer on the second p-type cladding layer side.

The total optical film thickness of the semiconductor layers present above the active layer 6 (i.e., the electron blocking layer 7 and the p-type semiconductor layer 8) in the light-emitting device 1 is preferably designed so that light emitted upward from the active layer 6, reflected at the p-side electrode 12 and travelling downward and light directly emitted downward from the active layer 6 amplify each other. When a central wavelength of the light emitted from the active layer 6 is defined as a wavelength, [nm], the total optical film thickness of the semiconductor layers present above the active layer 6 is, e.g., preferably not less than 0.5λ and not more than 1.4λ, more preferably not less than 0.5λ and not more than 0.8λ or not less than 1.0λ and not more than 1.3λ, even more preferably not less than 0.5λ and not more than 0.8λ.

The n-side electrode 11 is formed on an exposed surface 41 that is formed on the upper side of the n-type cladding layer 4 and is exposed from the active layer 6. The n-side electrode 11 can be, e.g., a multilayered film formed by sequentially stacking titanium (Ti), aluminum, titanium and gold (Au) on the n-type cladding layer 4. When the light-emitting element 1 is flip-chip mounted as described below, the n-side electrode 11 may be composed of a material that can reflect ultraviolet light emitted by the active layer 6.

The p-side electrode 12 is formed on an upper surface of the p-type semiconductor layer 8. The p-side electrode 12 can be made of, e.g., indium tin oxide (ITO), etc. When the light-emitting element 1 is flip-chip mounted as described below, the p-side electrode 12 may be composed of a material that can reflect ultraviolet light emitted by the active layer 6.

The light-emitting element 1 can be used in a state of being flip-chip mounted on a package substrate (not shown). That is, the light-emitting element 1 is mounted such that a side in the up-and-down direction, which is a side where the n-side electrode 11 and the p-side electrode 12 are provided, faces the package substrate and each of the n-side electrode 11 and the p-side electrode 12 is attached to the package substrate via a gold bump, etc. Light from the flip-chip mounted light-emitting element 1 is extracted on the substrate 2 side. However, it is not limited thereto and the light-emitting element 1 may be mounted on the package substrate by wire bonding, etc. In addition, although the light-emitting element 1 in the present embodiment is the light-emitting element 1 of so-called lateral type in which both the n-side electrode 11 and the p-side electrode 12 are provided on the upper side of the light-emitting element 1, it is not limited thereto and the light-emitting element 1 may be of the vertical type. The vertical light-emitting element 1 is the light-emitting element 1 in which the active layer 6 is sandwiched between the n-side electrode 11 and the p-side electrode 12. In this regard, when the light-emitting element 1 is of the vertical type, the substrate 2 and the buffer layer 3 are preferably removed by laser lift-off, etc.

### Method for Manufacturing the Light-Emitting Element 1

Next, an example of a method for manufacturing the light-emitting element 1 in the present embodiment will be described.

In the present embodiment, the buffer layer 3, the n-type cladding layer 4, the composition gradient layer 5, the active layer 6, the electron blocking layer 7 and the p-type semiconductor layer 8 are epitaxially grown on the disc-shaped substrate 2 in this order by the Metal Organic Chemical Vapor Deposition (MOCVD) method. That is, in the present embodiment, the disc-shaped substrate 2 is placed in a pocket of a susceptor arranged in a chamber and each semiconductor layer is formed on the substrate 2 by introducing source gases of each semiconductor layer to be formed on the substrate 2 into the chamber. The MOCVD method is sometimes called the Metal Organic Vapor Phase Epitaxy (MOVPE) method.

As the source gases to epitaxially grow each layer, it is possible to use trimethylaluminum (TMA) as an aluminum source, trimethylgallium (TMG) as a gallium source, ammonia (NH₃) as a nitrogen source, tetramethylsilane (TMSi) as a silicon source, and biscyclopentadienylmagnesium (Cp₂Mg) as a magnesium source.

In the method for manufacturing the light-emitting element 1 in the present embodiment, the silicon source is not supplied into the chamber during the deposition of the active layer 6, and silicon supplied before the deposition of the active layer 6 is diffused into the active layer 6. In the present embodiment, the silicon source is supplied into the chamber, e.g., during the deposition of the n-type cladding layer 4, during the deposition of the composition gradient layer 5 and right before the deposition of the active layer 6 (i.e., after the deposition of the composition gradient layer 5 and before the deposition of the active layer 6). Right before the deposition of the active layer 6, only the silicon source is supplied as the source gas into the chamber. Hereinafter, this step will be referred to as the “silicon source supply step”. In the silicon source supply step, a gas other than the source gas (e.g., a carrier gas such as hydrogen) may be introduced into the chamber as long as the gas supplied as the source gas is only the silicon source. By, e.g., adjusting the amount of the silicon source supplied in the silicon source supply step, the amount of silicon included in each layer of the active layer 6 is adjusted. In addition, due to the silicon source being supplied to portions with dislocations in the silicon source supply step, the growth mode of the matrix phase of the semiconductor layer changes and pits are formed during the deposition of the active layer 6.

Regarding the manufacturing conditions for epitaxially growing each semiconductor layer of wafer, such as growth temperature, growth pressure and growth time, etc., it is possible to appropriately adopt the conditions according to the configuration of each semiconductor layer.

To epitaxially grow each semiconductor layer on the substrate 2, it is also possible to use another epitaxial growth method such as the Molecular Beam Epitaxy (MBE) method or the Hydride Vapor Phase Epitaxy (HVPE) method.

After forming each semiconductor layer on the disc-shaped substrate 2, a mask is formed on a portion of the p-type semiconductor layer 8, i.e., a part other than the portion to be the exposed surface 41 of the n-type cladding layer 4. Then, the region in which the mask is not formed is removed by etching from the upper surface of the p-type semiconductor layer 8 to the middle of the n-type cladding layer 4 in the up-and-down direction. The exposed surface 41 exposed upward is thereby formed on the n-type cladding layer 4. After forming the exposed surface 41, the mask is removed.

Subsequently, the n-side electrode 11 is formed on the exposed surface 41 of the n-type cladding layer 4 and the p-side electrode 12 is formed on the p-type semiconductor layer 8. The n-side electrode 11 and the p-side electrode 12 may be formed by, e.g., a well-known method such as the electron beam evaporation method or the sputtering method. The object completed through the above process is cut into pieces with a desired dimension. Plural light-emitting elements 1 as shown in FIG. 1 are thereby obtained from one wafer.

### Functions and Effects of the Embodiment

In the light-emitting device 1 in the present embodiment, the full width at half maximum of an X-ray rocking curve for the (10-12) plane of the n-type cladding layer 4 (that is, the n-AlGaN mix value) is not more than 812 arcsec and silicon is included in the active layer 6. As a result, the light output of the light-emitting element 1 is improved, as shown in Experimental Example described later. It is a new finding that in case of the light-emitting element 1 in which silicon is included in the active layer 6, the light output is improved by setting the n-AlGaN mix value to not more than 812 arcsec.

Further, the n-AlGaN mix value preferably satisfies not less than 760 arcsec. In this case, the light output is more likely to be improved, as shown in Experimental Example described later.

In addition, the silicon concentration in the plural well layers 621 to 623 of the active layer 6 is higher in the layer closer to the n-type cladding layer 4. It has been confirmed that the light output of the light-emitting element 1 is likely to be improved by such a configuration. Such a configuration is easily achieved by forming the composition gradient layer 5 including silicon between the n-type cladding layer 4 and the active layer 6. That is, since silicon is diffused from the composition gradient layer 5 toward the active layer 6, it is easy to realize the configuration in which the silicon concentration in the well layers 621 to 623 is higher in the layer closer the n-type cladding layer 4.

In addition, the maximum value of the silicon concentration distribution in the active layer 6 in the up-and-down direction is not less than 8.0×10¹⁸ atoms/cm³. It has been confirmed that the light output of the light-emitting element 1 is thereby more likely to be improved.

In addition, the p-type semiconductor layer 8 has the p-type contact layer made of p-type GaN and the film thickness of the p-type contact layer is not more than 30 nm. The p-type contact layer made of p-type GaN is likely to absorb ultraviolet light, but by reducing the film thickness of the p-type contact layer to not more than 30 nm, absorption of ultraviolet light is suppressed and the light output of the light-emitting element 1 is improved.

As described above, according to the present embodiment, it is possible to provide a nitride semiconductor light-emitting element that can achieve improved light output in case that silicon is included in the active layer.

### Experimental Example

This Experimental Example is an example in which the relationship between the n-AlGaN mix value and light output was evaluated for wafers in Comparative Examples 1 to 14 in which silicon is not included in the active layer, and wafers in Examples 1 to 461 in which silicon is included in the active layer. Among the terms used in this Experimental Example onwards, the same terms as those used in the above-mentioned embodiment indicate the same contents as those in the above-mentioned embodiment, unless otherwise specified.

Comparative Examples 1 to 14 are wafers having the same basic configuration as the light-emitting element described in the embodiment, except that the composition gradient layer is not included and silicon is not included in the active layer. Comparative Examples 1 to 14 have the same basic structure as each other, except that the n-AlGaN mix values are different from each other.

Examples 1 to 344 of Examples 1 to 461 are wafers having the same basic configuration as Comparative Examples 1 to 14, except that silicon is included in the active layer. Examples 1 to 344 have the same configuration as each other, except that the n-AlGaN mix values are different from each other.

Examples 345 to 461 of Examples 1 to 461 are wafers different from Examples 1 to 344 in that silicon is included between the electron blocking layer and the p-type semiconductor layer and the p-type semiconductor layer has a different configuration. Examples 345 to 461 have the same configuration as each other, except that the n-AlGaN mix values are different from each other.

The structure, the film thickness of each layer, the Al composition ratio of each layer and the silicon concentration in each layer for Comparative Examples 1 to 14 are shown in Table 1 below. The structure, the film thickness of each layer, the Al composition ratio of each layer and the silicon concentration in each layer for Examples 1 to 344 are shown in Table 2 below. The structure, the film thickness of each layer, the Al composition ratio of each layer and the silicon concentration in each layer for Examples 345 to 461 are shown in Table 3 below.

TABLE 1

| Structure (Comparative | | Film | Al composition | Si concentration |
|---|---|---|---|---|
| Examples 1 to 14) | | thickness | ratio [%] | [atoms/cm³] |
| Substrate | | 430 ± 25 [um] | — | BG |
| Buffer layer | | 2000 ± 200 [nm] | 100 | |
| N-type semiconductor layer | | 2000 ± 200[nm] | 55 ± 10 | (1.50 ± 1.00)E+19 |
| Active layer | Barrier layer | 7 ± 5 [nm] | 85 ± 10 | BG |
| (3QW) | First well layer | 3 ± 1 [nm] | 45 ± 10 | |
| | Barrier layer | 7 ± 5 [nm] | 85 ± 10 | |
| | Second well layer | 3 ± 1 [nm] | 35 ± 10 | |
| | Barrier layer | 7 ± 5 [nm] | 85 ± 10 | |
| | Third well layer | 3 ± 1 [nm] | 35 ± 10 | |
| Electron | First electron | 1.5 ± 1 [nm] | 95 ± 5 | |
| blocking | blocking layer | | | |
| layer | Second electron | 25 ± 10 [nm] | 80 ± 10 | |
| | blocking layer | | | |
| P-type | P-type contact | 700 ± 100 [nm] | 0 | |
| semiconductor | layer | | | |
| layer | | | | |

TABLE 2

| Structure | | Film | Al composition | Si concentration |
|---|---|---|---|---|
| (Examples 1 to 344) | | thickness | ratio [%] | [atoms/cm³] |
| Substrate | | 430 ± 25 [um] | — | BG |
| Buffer layer | | 2000 ± 200 [nm] | 100 | |
| N-type semiconductor layer | | 2000 ± 200[nm] | 55 ± 10 | (1.50 ± 1.00)E+19 |
| Composition gradient layer | | 15 ± 5 [nm] | 55→85 | BG - Peak concentration |
| Active layer | Barrier layer | 7 ± 5 [nm] | 85 ± 10 | in First well layer* |
| (3QW) | First well layer | 5 ± 1 [nm] | 45 ± 10 | (3.50 ± 2.50)E+19 |
| | | | | (Peak concentration) |
| | Barrier layer | 7 ± 5 [nm] | 85 ± 10 | BG - Peak concentration |
| | | | | in First well layer* |
| | Second well layer | 3 ± 1 [nm] | 35 ± 10 | BG - 1.00E+19* |
| | Barrier layer | 7 ± 5 [nm] | 85 ± 10 | |
| | Third well layer | 3 ± 1 [nm] | 35 ± 10 | BG - 1.00E+18* |
| Electron | First electron | 1.5 ± 1 [nm] | 95 ± 5 | BG |
| blocking | blocking layer | | | |
| layer | Second electron | 25 ± 10 [nm] | 80 ± 10 | |
| | blocking layer | | | |
| P-type | P-type contact | 700 ± 100 [nm] | 0 | |
| semiconductor | layer | | | |
| layer | | | | |

TABLE 3

| Structure | | Film | Al composition | Si concentration |
|---|---|---|---|---|
| (Examples 345 to 461) | | thickness | ratio [%] | [atoms/cm³] |
| Substrate | | 430 ± 25 [um] | — | BG |
| Buffer layer | | 2000 ± 200 [nm] | 100 | |
| N-type semiconductor layer | | 2000 ± 200[nm] | 55 ± 10 | (1.50 ± 1.00)E+19 |
| Composition gradient layer | | 15 ± 5 [nm] | 55→85 | BG - Peak concentration |
| Active layer | Barrier layer | 7 ± 5 [nm] | 85 ± 10 | in First well layer* |
| (3QW) | First well layer | 5 ± 1 [nm] | 45 ± 10 | (3.50 ± 2.50)E+19 |
| | | | | (Peak concentration) |
| | Barrier layer | 7 ± 5 [nm] | 85 ± 10 | BG - Peak concentration |
| | | | | in First well layer* |
| | Second well layer | 3 ± 1 [nm] | 35 ± 10 | BG - 1.00E+19* |
| | Barrier layer | 7 ± 5 [nm] | 85 ± 10 | |
| | Third well layer | 3 ± 1 [nm] | 35 ± 10 | BG - 1.00E+18* |
| Electron | First electron | 1.5 ± 1 [nm] | 95 ± 5 | BG |
| blocking | blocking layer | | | |
| layer | Second electron | 25 ± 10 [nm] | 80 ± 10 | BG |
| | blocking layer | | | |
| | | | | (Peak concentration at |
| | | | | Interface between |
| | | | | Electron blocking layer |
| P-type | First p-type | 25 ± 10[nm] | 55 ± 10 | and P-type |
| semiconductor | cladding layer | | | semiconductor layer: |
| layer | | | | (2.00 ± 1.00)E+19) |
| | Second p-type | 3 ± 1 [nm] | 55→0 | BG |
| | cladding layer | | | |
| | P-type contact | 20 ± 5 [nm] | 0 | BG |
| | layer | | | |

The film thickness of each layer shown in Tables 1 to 3 was measured by a transmission electron microscope (TEM: Transmission Electron Microscopy). The Al composition ratio of each layer shown in Tables 1 to 3 is a value estimated from secondary ion intensity of Al measured by secondary ion mass spectrometry (SIMS). The figures in the column of Al composition ratio for Composition gradient layer in Tables 2 and 3 show that the Al composition ratio of the composition gradient layer along the up-and-down direction changes from 55% to 85% from the n-type cladding layer side to the active layer side. Likewise, the figures in the column of Al composition ratio for Second p-type cladding layer in Table 3 show that the Al composition ratio of the second p-type cladding layer along the up-and-down direction changes from 55% to 0% from the first p-type cladding layer side to the p-type contact layer side. The silicon concentration in each layer shown in Tables 1 to 3 was obtained using secondary ion mass spectrometry. In Tables 1 to 3, each part marked with “*” in the column of Si concentration means that the film thickness of the semiconductor layer is small and it is difficult to accurately measure the silicon concentration. In addition, “BG” in the column of Si concentration in Tables 1 to 3 means the background level. The background-level silicon concentration is a silicon concentration that would be detected when not doped with silicon.

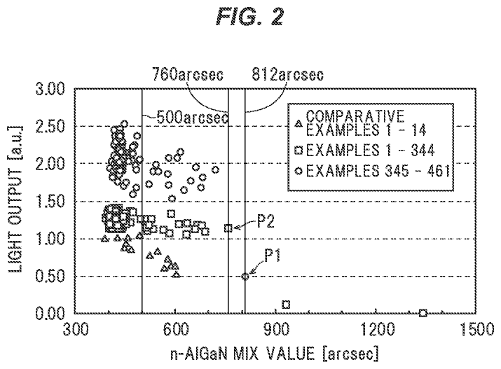

In this Experimental Example, light output when applying a current of 20 mA in the on-wafer state was measured on each of Comparative Examples 1 to 14 and Examples 1 to 461. Measurement of light output was conducted by a photodetector placed on the substrate side of each of the wafers in Comparative Examples 1 to 14 and Examples 1 to 461. FIG. 2 shows the relationship between the n-AlGaN mix value and the light output for each of Comparative Examples 1 to 14 and Examples 1 to 461. In FIG. 2, the results of Comparative Examples 1 to 14 are plotted with triangle symbols, the results of Examples 1 to 344 are plotted with square symbols, and the results of Examples 345 to 461 are plotted with circle symbols. In FIG. 2, the plotted square symbols overlap with each other and the plotted circle symbols overlap with each other, where the results of Examples 1 to 344 (i.e., the plotted square symbols) fall within the light output range from 1.00 [a.u.] to 1.50 [a.u.] and the results of Examples 345 to 461 (i.e., the plotted circle symbols) satisfies the light output of not less than 1.50 [a.u.].

As can be seen from FIG. 2, the results of Comparative Examples 1 to 14, in which silicon is not included in the active layer, show that the n-AlGaN mix value is preferably not more than 500 arcsec from the viewpoint of improving the light output. This result is similar to the result shown in FIG. 3 of JP 2019-121655A. That is, Experimental Example related to FIG. 3 of JP 2019-121655A is the result of using light-emitting elements in which silicon is not included in the active layer.

On the other hand, as can be seen from FIG. 2, the results of Examples 1 to 461, in which silicon is included in the active layer, show that high light output is obtained in a region where the n-AlGaN mix value is not more than 812 arcsec. That is, even when the n-AlGaN mix value is more than 500 arcsec, the light-emitting elements in which silicon is included in the active layer can achieve high light output as long as the n-AlGaN mix value satisfies not more than 812 arcsec, unlike Comparative Examples 1 to 14.

Here, at a plotted point P1 with the highest n-AlGaN mix value among the plotted circle symbols in FIG. 2 (i.e., the results of Examples 345 to 461), the n-AlGaN mix value is 812.1 arcsec and the result shows that the light output is relatively low. Therefore, in the configurations in which silicon is included in the active layer (i.e., Examples 1 to 461), the n-AlGaN mix value needs to be not more than 812 arcsec to improve the light output.

A plotted point P2 among the plotted square symbols (i.e., the results of Examples 1 to 344) is the result with the highest n-AlGaN mix value, among the results which are plotted with the square symbols and show high light output. The n-AlGaN value for the plotted point P2 was 760.0 arcsec, indicating that the n-AlGaN mix value of not more than 760 arcsec is more preferable for the configuration in which silicon is included in the active layer.

In addition, when comparing the results of Examples 1 to 344 with the results of Examples 345 to 461, Examples 345 to 461 have higher light output. The main reason for this is thought to be that in Examples 345 to 461, the film thickness of the p-type contact layer is thinner than in Examples 1 to 344 and absorption of ultraviolet light by the p-type contact layer is suppressed.

The lowest n-AlGaN mix value among Examples 1-344 was 394.2 arcsec, and the lowest n-AlGaN mix value among Examples 345-461 was 406.5 arcsec. When the n-AlGaN mix value is lower (i.e., when the crystal quality of the n-type cladding layer is higher), the light output tends to be more improved, hence, it is predicted that light-emitting elements with lower n-AlGaN mix values than Examples 1 to 461 have the same or improved light output as compared to Examples 1 to 461.

### Summary of the Embodiment

Technical ideas understood from the embodiment will be described below citing the reference signs, etc., used for the embodiment. However, each reference sign, etc., described below is not intended to limit the constituent elements in the claims to the members, etc., specifically described in the embodiment.

The first feature of the invention is a nitride semiconductor light-emitting element 1, comprising: an n-type semiconductor layer 4 comprising Al, Ga and N; an active layer 6 that is formed on one side of the n-type semiconductor layer 4 and has a multiple quantum well structure with a plurality of well layers 621-623 comprising Al, Ga and N; and a p-type semiconductor layer 8 formed on a side of the active layer 6 opposite to the n-type semiconductor layer 4, wherein a full width at half maximum of an X-ray rocking curve for a (10-12) plane of the n-type semiconductor layer 4 is not more than 812 arcsec, and wherein silicon is included in the active layer 6.

It is thereby possible to improve the light output of the nitride semiconductor light-emitting device 1 in which silicon is included in the active layer 6.

The second feature of the invention is that, in the first feature, the full width at half maximum is not more than 760 arcsec.

It is thereby possible to further improve the light output of the nitride semiconductor light-emitting device 1 in which silicon is included in the active layer 6.

The third feature of the invention is that, in the first or second feature, a silicon concentration in the plurality of well layers 621-623 of the active layer 6 is higher in the layer closer to the n-type semiconductor layer 4.

It is thereby possible to further improve the light output of the nitride semiconductor light-emitting device 1.

The fourth feature of the invention is that, in the third feature, a maximum value of a silicon concentration distribution in the active layer 6 in a stacking direction of the n-type semiconductor layer 4, the active layer 6 and the p-type semiconductor layer 8 is not less than 8.0×10¹⁸ atoms/cm³.

It is thereby possible to further improve the light output of the nitride semiconductor light-emitting device 1.

The fifth feature of the invention is that, in the third or fourth feature, a composition gradient layer 5, which has an Al composition ratio increasing toward the active layer 6 and comprises silicon, is formed between the n-type semiconductor layer 4 and the active layer 6.

The configuration of the third feature is thereby easily realized.

The sixth feature of the invention is that, in any one of the first to fifth features, the p-type semiconductor layer 8 comprises a p-type contact layer comprising p-type GaN, and wherein a film thickness of the p-type contact layer is not more than 30 nm. It is thereby possible to further improve the light output of the nitride semiconductor light-emitting device 1.

### Additional Note

Although the embodiment of the invention has been described, the invention according to claims is not to be limited to the embodiment described above. Further, please note that not all combinations of the features described in the embodiment are necessary to solve the problem of the invention. In addition, the invention can be appropriately modified and implemented without departing from the gist thereof.

1. A nitride semiconductor light-emitting element, comprising:
an n-type semiconductor layer comprising Al, Ga and N;
an active layer that is formed on one side of the n-type semiconductor layer and has a multiple quantum well structure with a plurality of well layers comprising Al, Ga and N; and
a p-type semiconductor layer formed on a side of the active layer opposite to the n-type semiconductor layer,
wherein silicon is included in the active layer, and
wherein a full width at half maximum of an X-ray rocking curve for a (10-12) plane of the n-type semiconductor layer is not more than 812 arcsec.

2. The nitride semiconductor light-emitting element according to claim 1, wherein the full width at half maximum is not more than 760 arcsec.

3. The nitride semiconductor light-emitting element according to claim 1, wherein a silicon concentration in the plurality of well layers of the active layer is higher in the layer closer to the n-type semiconductor layer.

4. The nitride semiconductor light-emitting element according to claim 3, wherein a maximum value of a silicon concentration distribution in the active layer in a stacking direction of the n-type semiconductor layer, the active layer and the p-type semiconductor layer is not less than 8.0×10¹⁸ atoms/cm³.

5. The nitride semiconductor light-emitting element according to claim 3, wherein a composition gradient layer, which has an Al composition ratio increasing toward the active layer and comprises silicon, is formed between the n-type semiconductor layer and the active layer.

6. The nitride semiconductor light-emitting element according to claim 1, wherein the p-type semiconductor layer comprises a p-type contact layer comprising p-type GaN, and wherein a film thickness of the p-type contact layer is not more than 30 nm.
